(19) United States
(12) Patent Application Publication
(10) Pub. No.: US 2013/0270623 A1
(43) Pub. Date: Oct. 17, 2013

(54) SEMICONDUCTOR MEMORY DEVICE AND MANUFACTURING METHOD OF SEMICONDUCTOR MEMORY DEVICE

(71) Applicant: KABUSHIKI KAISHA TOSHIBA, Tokyo (JP)

(72) Inventors: Ryota SUZUKI, Mie (JP); Tatsuya Kato, Mie (JP)

(21) Appl. No.: 13/791,351

(22) Filed: Mar. 8, 2013

(30) Foreign Application Priority Data
Apr. 16, 2012 (JP) 2012-092752

(51) Int. Cl. H01L 29/788; H01L 29/66

(52) U.S. Cl. CPC H01L 29/788; H01L 29/66825
USPC 257/316; 438/258

(57) ABSTRACT

According to one embodiment, a semiconductor memory device has plural memory cells arranged on a semiconductor substrate, plural select transistors for selecting the memory cell for carrying out record or read, and an insulating film arranged between adjacent memory cells and between adjacent select transistors. The memory cell and select cell transistors include gates extending the same distance from the substrate, and an insulator between adjacent select cell transistors, between the select cell transistors and the memory transistors, and between adjacent memory transistors, the height of the insulator between the select cell transistors is higher than between the select cell transistors and the memory transistors, and between adjacent memory transistors. An insulating layer deposited thereover is deposited having an in situ flatness, without further planarization.

### CROSS-REFERENCE TO RELATED APPLICATION

This application is based upon and claims the benefit of priority from Japanese Patent Application No. 2012-092752, filed Apr. 16, 2012; the entire contents of which are incorporated herein by reference.

### FIELD

Embodiments described herein relate to a semiconductor memory device and a manufacturing method of the semiconductor memory device.

### BACKGROUND

In recent years, for NAND-type flash memory devices and other semiconductor memory devices, there has been an ever rising demand to reduce the size, and device to device spacing, in the memory array. As the memory cell width is reduced, the aspect ratio i.e., the height of the memory cell divided by the width memory cell, increases.

Additionally, the pitch or spacing of the memory region of the cell is often different than that in the peripheral region of the cell, and as a result a high of an insulating film in the memory region and the peripheral region is different according to deposition processes. In order to eliminate the height difference between the memory cells regions with a large aspect ratio and the peripheral region, CMP is used to flatten the insulating film. Using CMP (Chemical Mechanical Polishing), the raised surfaces of the film layer(s) is removed to improve the flatness of the surface of the semiconductor wafer during the manufacturing process. On the other hand, when CMP is carried out, damage due to mechanical polishing, such as cracks of films and defects in crystal of the semiconductor layers, and the like, may take place, and this may lead to decrease in the manufacturing yield.

The damage caused by mechanical polishing in CMP operation tends to take place when the flatness of the surface before CMP is poor. When the damage caused by mechanical polishing take place in the memory cell portion of a semiconductor memory device, depending on the degree of the damage, the redundancy region may be used to meet the specifications of the device. However, when the damage caused by mechanical polishing in CMP take place near the contact portions of the semiconductor memory device, DC defects, contact open defects, bit line short circuit defects, and the like often take place for the semiconductor memory device, and it is impossible to use the redundancy region to cover them up.

### DESCRIPTION OF THE DRAWINGS

FIG. 1 is an equivalent circuit diagram illustrating a portion of the electrical configuration of the semiconductor memory device in an embodiment of the present disclosure.

FIG. 2 is a plane view illustrating a portion of the layout configuration of the semiconductor memory device.

FIG. 3 is a vertical cross-sectional view taken across A-A in FIG. 2 and schematically illustrating the configuration.

FIG. 4 is a schematic vertical cross-sectional view illustrating a step of operation in the manufacturing process.

FIG. 5 is a schematic vertical cross-sectional view illustrating a step of operation in the manufacturing process.

FIG. 6 is a schematic vertical cross-sectional view illustrating a step of operation in the manufacturing process.

FIG. 7 is a schematic vertical cross-sectional view illustrating a step of operation in the manufacturing process.

FIG. 8 is a schematic vertical cross-sectional view illustrating a step of operation in the manufacturing process.

FIG. 9 is a schematic vertical cross-sectional view illustrating a step of operation in the manufacturing process.

FIG. 10 is a schematic vertical cross-sectional view illustrating a step of operation in the manufacturing process.

FIG. 11 is a schematic vertical cross-sectional view illustrating a step of operation in the manufacturing process.

FIG. 12 is a block diagram illustrating the semiconductor memory device.

FIG. 13 is a vertical cross-sectional view of a peripheral transistor.

### DETAILED DESCRIPTION

Embodiments provide a semiconductor memory device and a manufacturing method of semiconductor memory device that can alleviate the problem of decrease in the manufacturing yield of the semiconductor memory devices caused by the damage that take place near the contact portions of the semiconductor memory devices during polishing thereof.

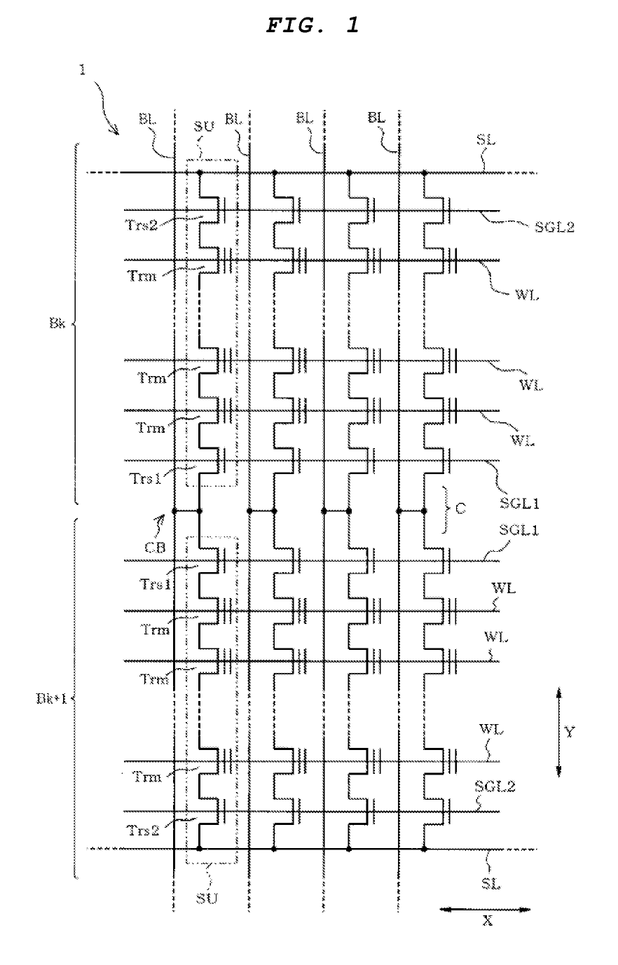

In general, according to one embodiment, an NAND-type flash memory semiconductor memory device will be explained with reference to FIGS. 1 to 11. The same numbers will be used throughout the drawings in the explanation of the various embodiments, so the explanation of the corresponding feature will not be repeated. However, the drawings are merely schematic diagrams, and the relationship between thickness and planer dimensions, proportions of the thickness values of the various layers, and the like may be different from an actual device. In the following explanation, the phrases of upper/lower, and the like related to direction refers to the relative directions with the side of the semiconductor substrate where the elements are formed taken as the upper side. They may be different from the actual directions with reference to a gravity acceleration direction.

An embodiment of the present disclosure provides a semiconductor memory device having plural memory cells arranged on a semiconductor substrate, plural select transistors for selecting the memory cell for carrying out recording or reading of the cell, and an insulating film arranged between the adjacent memory cells and between the adjacent select transistor. In this semiconductor memory device, the surface of the semiconductor substrate where the memory cells are arranged faces upward, and the distance between the upper surface of the insulating film, which is arranged between the select transistors, and the upper surface of the gate electrodes of the select transistors is smaller than the distance between the upper surface of the insulating film, which is arranged between the adjacent memory cells, and the upper surface of the gate electrodes of the memory cells.

An embodiment of the present disclosure provides a manufacturing method of a semiconductor memory device, whereby plural memory cells and plural select transistors for selecting the memory cell to carry out recording or reading thereof are formed on a semiconductor substrate; an insulating film is formed between the adjacent memory cells and between the adjacent select transistors; a mask is formed on the upper surface of the insulating film between at least a portion of the upper surface of the select transistors and the select transistors; the upper surface position of the insulating film between the memory cells reduced or lowered to a level below the upper surface of the gate electrodes of the memory cells; the mask is removed; contacts passing through the insulating film between the select transistors are formed; and wiring that is electrically connected to the select transistors via the contacts is formed.

FIG. 1 is an equivalent circuit diagram illustrating a portion of the memory cell array formed in the memory cell region of the semiconductor memory device 1.

The semiconductor memory device 1 has a memory cell array that has the NAND cell units SU arranged in a matrix configuration, with each of the NAND cell units SU including two select gate transistors Trs1, Trs2, a plurality (e.g., 64) of memory cell transistors Trm connected in series between the select gate transistors Trs1, Trs2, and dummy memory cells (not shown in the drawing) as needed. In the NAND cell units SU, for the plural memory cell transistors Trm, the adjacent memory cell transistors share the source/drain regions.

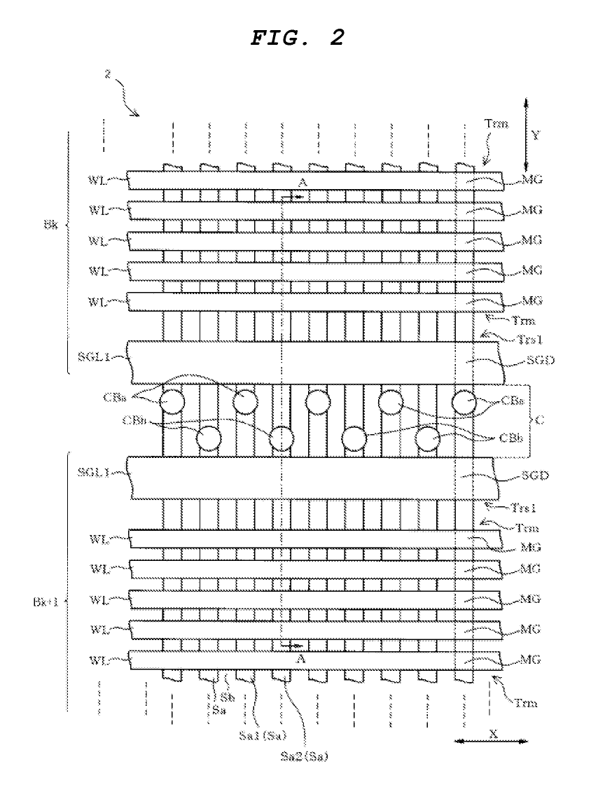

The memory cell transistors Trm arranged in the X-direction (word line direction) in FIG. 1 are connected by the word lines WL. The select gate transistors Trs1 arranged in the X-direction in FIG. 1 are connected by select gate line SGL1, and the select gate transistors Trs2 are connected by the select gate line SGL2. The bit line contacts CB (corresponding to CBa, CBb in FIG. 2) are connected to the drain regions of the select gate transistors Trs1. The bit line contacts CB are connected to the bit line BL extending in the Y-direction (bit line direction) orthogonal to the X-direction in FIG. 1. Also, the select gate transistors Trs2 are connected via the source regions to the source line SL extending in the X-direction shown in FIG. 1.

FIG. 2 is a plane top view illustrating the physical layout pattern of a portion of the memory cell region. As shown in FIG. 2, on a semiconductor substrate 2, the element isolating regions Sb having an STI (shallow trench isolation) structure are formed extending in the Y-direction as shown in FIG. 2. Plural element isolating regions Sb are formed with a prescribed interval between each other. As a result, plural element regions Sa are formed extending in the Y-direction as shown in FIG. 2, and plural element regions Sa are formed there between and electrically separated from each other in the X-direction.

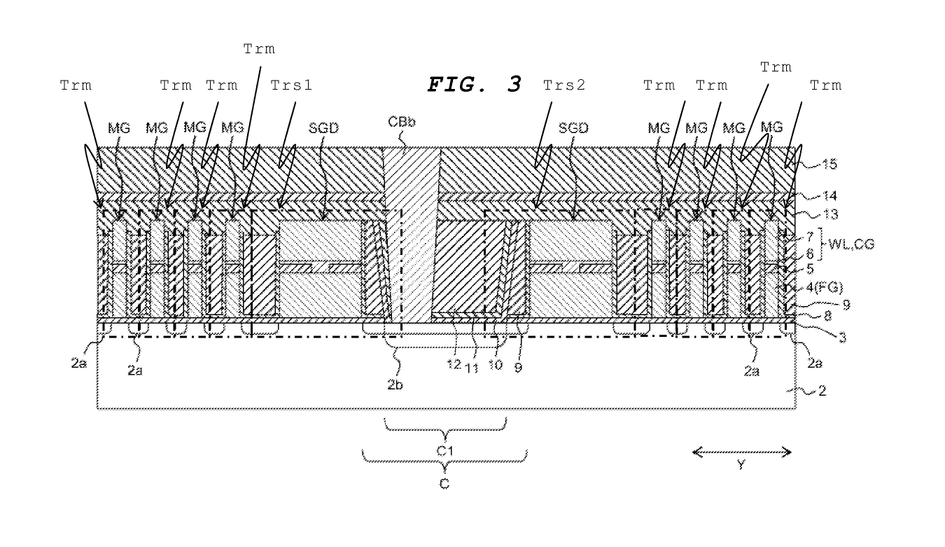

The word lines WL are formed to extend in the X-direction, thereby crossing the element regions Sa extending in the Y-direction as shown in FIG. 2. The plural word lines WL are formed with a prescribed Y-direction spacing as shown in FIG. 2. Above the element regions Sa crossing with the word lines WL, the memory cell gate electrodes MG (see FIG. 3) of the memory cell transistors Trm are formed.

As shown in FIG. 1, the plural memory cell transistors Trm adjacent each other in the Y-direction and connected with each other in series become a portion of the NAND column (memory cell string). The select gate transistors Trs1, Trs2 are arranged adjacent the two outer sides in the Y-direction of the end portion memory cells of the NAND column.

Plural select gate transistors Trs1 are arranged in the X-direction, and the select gate electrodes SGD of the plural select gate transistors Trs1 (see FIGS. 2 and 3) are electrically connected by the select gate line SGL1. On the element regions Sa crossing the select gate line SGL1, the select gate electrodes SGD of the select gate transistors Trs1 are formed.

Also, as shown in FIG. 1, plural select gate transistors Trs2 are formed in the X-direction, and the select gate electrodes (not shown in the FIGS. 2 and 3) of the plural select gate transistors Trs2 are electrically connected by the select gate line SGL2. On the element regions Sa crossing with the select gate line SGL2, too, the select gate electrodes (not shown in the drawing) are formed.

As shown in FIG. 1, the a bit line contact region C (see FIGS. 1 to 3) is arranged between the select gate transistors Trs1-Trs1 of the NAND cell units SU-SU adjacent each other in the Y-direction. In the bit line contact region C, plural bit line contacts CBa, CBb (FIG. 2) are formed.

The plural bit line contacts CBa, CBb are formed on plural element regions Sa1, Sa2, which extend in the Y-direction, and alternate in the Y-direction, of FIG. 2, to individually interconnect. The bit line contacts CB are formed to individually interconnect the element regions Sa between the adjacent select gate transistors Trs1-Trs1.

As shown in FIG. 2, the bit line contacts CBa formed on the first element regions Sa1 (Sa) are arranged the select gate lines SGL1 (select gate electrodes SGD) of the block Bk. In addition, the bit line contacts CBb formed on the second element region Sa2 (Sa) are arranged adjacent to the select gate lines SGL1 (select gate electrodes SGD) of the block Bk+1.

Consequently, the bit line contacts CBa, CBb are arranged in zigzag configuration by shifting with respect to each other in the Y-direction as they are located in the x direction on each adjacent element region Sa. As a result, the spacing between the bit line contacts CBa-CBb is increased. Although not shown in the drawing, the source line contact is formed on the element region Sa between a pair of select gate lines SGL2-SGL2.

FIG. 3 is a schematic diagram illustrating a sectional view at section A-A of FIG. 2. FIG. 3 illustrates the peripheral cross-sectional structure in the Y-direction of FIG. 2 of the pair of select gate transistors Trs1, Trs1, and the bit line contact CBb between the select gate transistors Trs1-Trs1. It will be understood that, the cross-sectional structure in the Y-direction of the bit line contacts CBa is nearly identical, except the contact CBa is shifted to the right hand side of the space between two select gate electrodes SGD.

As shown in FIG. 3, a gate insulating film 3 is formed on the semiconductor substrate 2 (e.g., a p-type silicon substrate). For example, the gate insulating film 3 may be made of a silicon oxide film, and it is formed on the upper surface of the semiconductor substrate 2 in the region where the memory cell transistors Trm and select gate transistors Trs1 are formed. This gate insulating film 3 is not formed on the semiconductor substrate 2 in the central region C1 of the substrate to which underlies the formation region of bit line contacts CBa, CBb.

The memory cell transistors Trm contain memory cell gate electrodes MG and source/drain regions 2a formed on the gate insulating film 3, and source/drain regions 2a formed in the substrate 2 in position, underlying each.

Each of the memory cell gate electrodes MG is formed by sequentially laminating the following parts on the gate insulating film 3: a floating gate electrode (charge accumulating layer) FG using an impurity-doped polysilicon layer 4, an inter-gate insulating film 5, and a control gate electrode CG.

The source/drain regions 2a are formed at the upper surface of the semiconductor substrate 2 on the flanks of the memory cell gate electrodes MG. The inter-gate insulating film 5 is an insulating film located between the floating gate electrode FG and the control gate electrode CG. It may be an polysilicon insulating film, an inter-electroconductive-layer insulating film, or an inter-electrode insulating film.

The inter-gate insulating film 5 may be a laminated structural film (ONO film) having an oxide film/nitride film/oxide film structure. However, one may also adopt a NONON film prepared by forming a nitride film before and or after and formation of the (ONO) film.

The control gate electrode CG contains an impurity-doped polysilicon layer 6, and a silicide layer 7 formed on the polysilicon layer 6. The silicide layer 7 can be formed by converting the upper portion of the polysilicon layer 6 to silicide by a low-resistance-converting metal. Here, the low-resistance-converting metal may be any of the following transitional metals: nickel (Ni), titanium (Ti), cobalt (Co), platinum (Pt), palladium (Pd), tantalum (Ta), molybdenum (Mo), and the like.

As shown in FIG. 3, plural memory cell transistors Trm are formed adjacent each other in the Y-direction. The select gate transistors Trs1 are formed adjacent to the memory cell transistors Trm, respectively.

The select gate electrodes SGD of the select gate transistors Trs1 have almost the same structure as the memory cell gate electrodes MG of the memory cell transistors Trm. For example, they each have a laminated structure of the polysilicon layer 4, the inter-gate insulating film 5, the polysilicon layer 6, and the silicide layer 7, and a through hole is formed close to the center of the inter-gate insulating film 5. The structure has the polysilicon layer 4 and the polysilicon layer 6 in contact with each other, so that the function of the inter-gate insulating film 5 between these insulating layers is prevented. Although the cross-sectional structure is not shown in the drawing, the select gate electrodes of the select gate transistors Trs2 have the same structure as that of the select gate electrodes SGD.

In addition, the memory cell gate electrodes MG of the memory cell transistors Trm and the select gate electrodes SGD of the select gate transistors Trs1 are aligned in the Y-direction.

An oxide film 8 is formed along the side walls of the memory cell gate electrodes MG between adjacent memory cell gate electrodes MG-MG, and on either side of the select gate electrodes SGD. The upper (furthest from substrate 2) extension of the oxide film 8 is located slightly above the center of the silicide layer 7, from there it is formed downwardly along the side walls of the polysilicon layer 6, the inter-gate insulating film 5, and the polysilicon layer 4, and, over the upper surface of the gate insulating film 3 (or the semiconductor substrate 2) between the memory cell gate electrodes MG-MG.

The oxide film 8 is also formed along the side walls of the corresponding memory cell gate electrodes MG and select gate electrodes SGD between the memory cell gate electrodes MG and the select gate electrodes SGD. For the oxide film 8, its upper end is located near the center in the longitudinal direction of the silicide layer 7, and, below the portion, it is formed downward along the side walls of the polysilicon layer 6, the inter-gate insulating film 5, and the polysilicon layer 4, and, at the same time, it is formed along the upper surface of the gate insulating film 3 (or the semiconductor substrate 2) between the memory cell gate electrodes MG-MG. In the bit line contact region C between the select gate electrodes SGD-SGD, the oxide film 8 has its upper end coterminus with upper surface of the silicide layer 7, and it there from along the side wall of the select gate electrodes SGD. Also, the oxide film 8 is formed towards the side of the central region C1 in the Y-direction of the bit line contact region C. That is, the oxide film 8 is formed along the upper surface of the gate insulating film 3 (or the semiconductor substrate 2) excluding the central region C1 (see FIG. 3) in the Y-direction of the bit line contact region C. The oxide film 8 is formed as a protective film for protecting the side walls of the select gate electrodes SGD and the memory cell gate electrodes MG.

An insulating film 9 overlies the oxide film 8 along the side of the select gate electrode (SGD). In the central region C1 of the bit line contact region C, an oxide film 10 is formed along, and contacts, the upper surface of the semiconductor substrate 2. As shown in FIG. 3, the oxide film 10 in the central region C1 extends upwardly adjacent to the sides of the select gate electrodes SGD over the insulating layer 9 on both sides of the bit line contact region C in the Y-direction. The oxide film 10 terminates along the side of the select gate electrodes SGD adjacent in the end of the oxide film 8 and the upper face of the silicide layer 7.

A nitride film 11, which may be used as a hard mask, is formed on the upper surface of the oxide film 10. As shown in FIG. 3, the nitride film 11 in the central region C1 also extends along the upper surface of the semiconductor substrate 2, and at the same time, it is formed inclined (or curved) towards the sides of the select gate electrodes SGD on both sides in the Y-direction of the bit line contact region C The nitride film 11 the height of the upper end in the longitudinal direction inclined towards the sides of the select gate electrodes SGD is located near the upper end of the oxide film 8, the upper end in the longitudinal direction of the silicide layer 7, and the upper end in the longitudinal direction of the oxide film 10. On the upper surface of the nitride film 11, an NSG film 12 (the first insulating film) is located as the interlayer insulating film. The adjacent NSG film 12, extends from the substrate to a height adjacent to the upper end of the oxide film 8, the upper end in the longitudinal direction of the silicide layer 7, and the upper ends in the longitudinal direction of the oxide film 10 and the nitride film 11. As shown in FIG. 3, both the oxide film 10 and the nitride film 11 have upwardly extending portions located at both sides of the NSG film 12. Consequently, as shown in the drawing, the NSG film 12 is buried on the inner side of the bit line contact region C of the extending portions.

The NSG film 12 is formed so that its cross-sectional area tapers from a larger thickness adjacent the upper surface of the semiconductor substrate 2, to a smaller as it approaches the substrate 2. The NSG film 12 is formed with an inverted taper surface having its two side surfaces in the Y-direction as slopes towards the sides of the select gate electrodes SGD, SGD on the two sides of the bit line contact region C from the upper surface of the semiconductor substrate 2 upward (or convex curved surfaces upward to the side of the central region C1).

An oxide film 13 is formed over the select gate electrodes SGD and the memory cell gate electrodes MG. The oxide film 13 is formed along the upper surface of the silicide layer 7 of the memory cell gate electrodes MG and the select gate electrodes SGD, and, at the same time, it is also formed on the upper side wall surface (upper side surface) of the silicide layer 7 of the memory cell gate electrodes MG. It is also formed on the upper surface on the side opposite to the side of the bit line contact region C among the upper side wall surface (upper side surface) of the silicide layers 7 of the select gate electrodes SGD. Consequently, the oxide film 13 covers the exposed region of the silicide layer 7 that is above the upper end of the oxide film 8 of each of the memory cell gate electrodes MG and select gate electrodes SGD (the position lower than the center of the silicide layer 7).

The insulating film 9 is formed between the portion of the oxide film 8 between the memory cell gate electrodes MG-MG and the portion of the oxide film between the memory cell gate electrodes MG-select gate electrode SGD. For the insulating film 9, the height of its upper surface is located near the center in the longitudinal direction of, e.g., the silicide layer 7, and it is formed from the portion downward along the oxide film 8. At the same time, it is formed along the oxide film 8 on the upper surface of the gate insulating film 3 (or the semiconductor substrate 2) between the memory cell gate electrodes MG-MG.

Also, the insulating film 9 (the second insulating film) is also formed between the oxide film 8 between the select gate electrodes SGD-the NSG film 12 and the oxide film 10. For the insulating film 9, the height of its upper surface is located near the upper end of the oxide film 8, the upper end in the longitudinal direction of the silicide layer 7, and the upper ends in the longitudinal direction of the oxide film 10, the nitride film 11 and the NSG film 12. In other words, between the select gate electrodes SGD-SGD, the heights from the semiconductor substrate 2 are nearly the same at the upper end of the oxide film 8, on the upper surface of the insulating film 9, at the upper end of the silicide layer 7, near the upper ends of the oxide film 10 and the nitride film 11 in the longitudinal direction, and on the upper surface of the NSG film 12.

A nitride film 14 is formed on the oxide film 13. The nitride film 14 works as a hard mask film for the anisotropic etching (RIE method) carried out when the bit line contacts CB (CBa, CBb) are formed, and as a barrier insulating film that barriers the undesired substances (such as carbon, hydrogen) when the film is manufactured in the later step of operation. An oxide film 15 is formed on the nitride film 14. This oxide film 15 may be a silicon oxide film formed using TEOS (tetra-ethyl ortho-silicate).

In the central region C1 of the bit line contact region C, a high concentration impurity diffusion layer 2b is formed into the upper surface of the semiconductor substrate 2. The bit line contacts CBa and CBb are formed through the oxide film 15, the nitride film 14, the oxide film 13, the NSG film 12, the nitride film 11, and the oxide film 10 so that they are in contact on the impurity diffusion layer 2b. These bit line contacts CBa and CBb may be formed as contacts coated by tungsten (W) as a barrier metal.

As shown in FIG. 3, in a cross-sectional view, the bit line contact CBb is formed. This bit line contact CBb is formed near the side of the select gate electrode SGD on the left hand side shown in FIG. 3. As shown in FIG. 2 instead of FIG. 3, the bit line contact CBa is formed near the side of the select gate electrode SGD on the right hand side in FIG. 3.

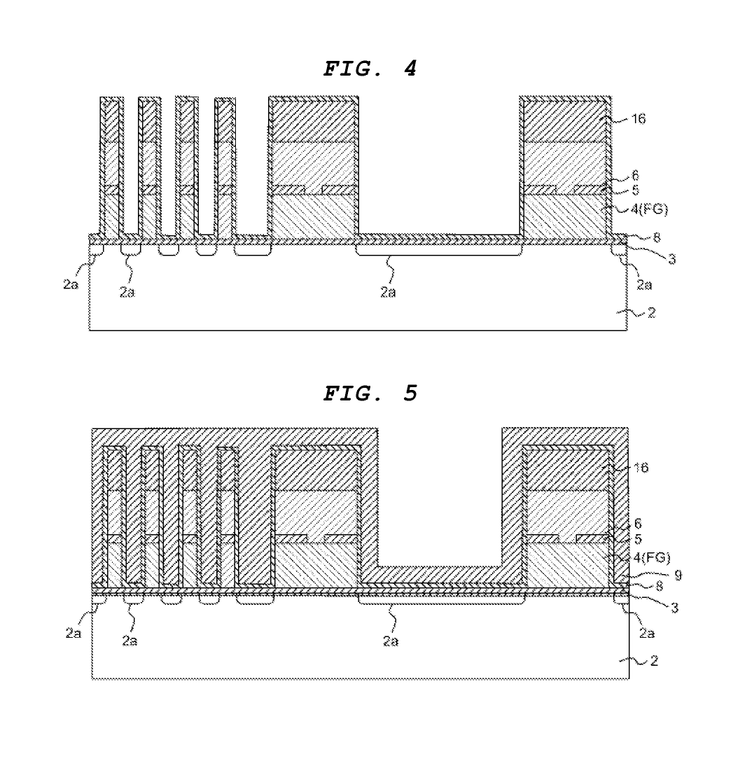

In the following, an example of the manufacturing method of the configuration will be explained with reference to FIG. 4 and the figures thereafter. In the explanation of the present embodiment, explanation will be mainly explained for the characteristic features. For the conventional steps of operation, other steps of operation may be added between the various steps of operation, and steps of operation can be deleted as needed. Also, as long as practically available, the various steps of operation can be exchanged.

As shown in FIG. 3, the cross-sectional structure in the Y-direction has a nearly linear symmetric structure around the bit line contact region Cas the center. Consequently, in FIG. 4 and the figures after that (FIGS. 4 to 13), only a portion of the cross-sectional structure on the side of the NAND cell units SU is shown.

As shown in FIG. 4, the gate insulating film 3 is formed on the semiconductor substrate 2. According to the present embodiment, a p-type silicon substrate is adopted as the semiconductor substrate 2. Consequently, by a thermal oxidation treatment for the upper surface of the silicon substrate, a silicon oxide film is formed to create the gate insulating film 9. Then, as the material for the floating gate electrode FG, a polysilicon layer 4 (the first gate electrode film) is formed by a low pressure CVD (chemical vapor deposition) method. In this case, it is preferred that phosphorus (P), an n-type impurity, is used as the impurity.

Then, although not shown in the drawing, the upper portion of the polysilicon layer 4 and the semiconductor substrate 2 is treated by photolithographic etching technology so that it is patterned in the direction (X-direction) perpendicular to the surface shown in FIG. 4, and an element isolating insulating film (not shown in the drawing) is buried in the dividing regions, so that the element isolating regions Sb are formed to divide portion to plural element regions Sa.

Then, on the polysilicon layer 4, the LP-CVD method is used to deposit the inter-gate insulating film 5 forming ONO aluminum film or the like. Also, a NONON film prepared by radical nitride formation treatment may also be adopted before or after forming the ONO film, so that a film containing aluminum oxide (alumina) is formed instead of the intermediate nitride film. Then, on the inter-gate insulating film 5, the second gate electrode film is formed from the polysilicon layer 6. Then, on the polysilicon layer 6, a nitride film 16 is formed as the cap film using the CVD method.

Then, after an oxide film is deposited on the nitride film 16 (not shown in the drawing) as the hard mask for dry etching processing, a photoresist (not shown in the drawing) is coated thereon, and the photoresist is patterned using the photolithographic technology. Then, after patterning of the hard mask using the resist pattern as a mask, the hard mask is used as a mask to carry out anisotropic etching (such as RIE) of the nitride film 16.

Thereafter, anisotropic etching is carried out for the polysilicon layer 6, the inter-gate insulating film 5 and the polysilicon layer 4 to divide the base portions (laminated gate electrodes) of the memory cell gate electrodes MG and select gate electrodes SGD. In this manufacturing operation, the gate insulating film 3 may also be removed.

Then, a oxide film 8 is formed by an ALD (Atomic Layer Deposition) method. The oxide film 8 is formed along the upper surface of the gate insulating film 3 (or the semiconductor substrate 2), the side surface of the polysilicon layer 4, the side surface of the inter-gate insulating film 5, the side surface of the polysilicon layer 6, and on the upper surface and side surface of the nitride film 16, i.e., over all exposed surfaces in FIG. 4.

Then, using the base portions (the laminated gate electrodes) of the memory cell gate electrodes MG and the select gate electrodes SGD as mask, dopants (phosphorus when an n-type dopant is used) is ion implanted in a self aligned way into the upper surface of the semiconductor substrate 2 using conventional ion implanting methods. Then, a heat treatment needed for activating the impurity is carried out so that a diffusion layer is formed as the source/drain regions 2a. As a result, the structure shown in FIG. 4 can be formed.

Here, only the diffusion layer in the memory cell region is shown. For the practical nonvolatile semiconductor memory device, the following operation is carried out concurrently with the present operation: a peripheral circuit for driving the memory cells is arranged, and the diffusion layer of the transistors needed for operation of the peripheral circuit is formed.

Then, as shown in FIG. 5, using the ALD method, the insulating film 9 is formed over the exposed surfaces of FIG. 4, to cover the film 8 overlying the electrodes of the gate electrodes MG-SGD and between the laminated gate electrodes of the gate electrodes MG-MG. For example, an oxide film may be used as the insulating film 9. It is preferred that the oxide film 8 and insulating film 9 be formed using the ALD method. However, one may also use the LP-CVD method or the plasma CVD method.

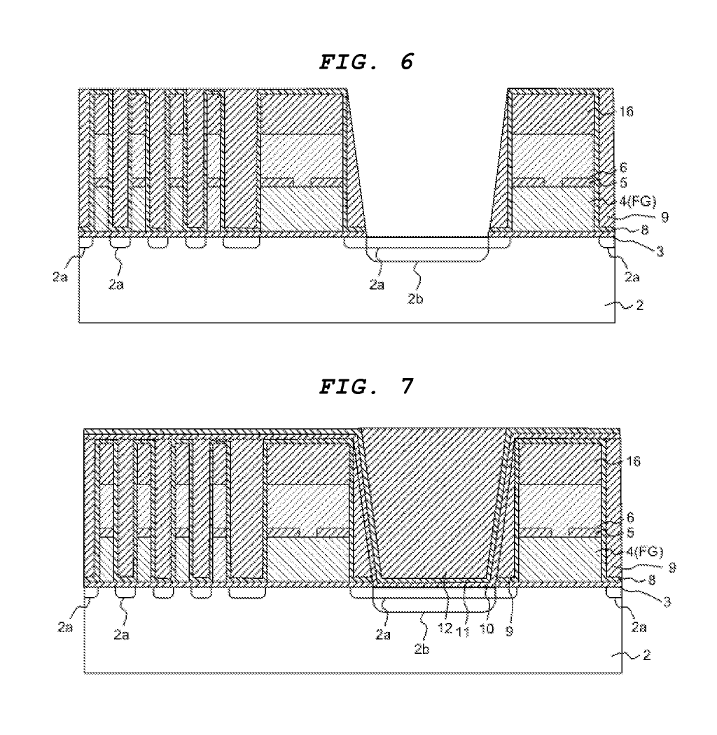

Then, as shown in FIG. 6, the insulating film 9 is subject to RIE anisotropic etching until the upper surface of the oxide film 8 (or the upper surface of the nitride film 16) is exposed, so that a recess is formed on the central region C1 of the bit line contact region C, and the portions of the oxide film 8 and gate insulating film 3 at the base of the recess are removed, so that the surface of the semiconductor substrate 2 is exposed in the recess.

In this case, the interval between the laminated gate electrodes of the select gate electrodes SGD-SGD is formed larger than the interval between the laminated gate electrodes of the gate electrodes SGD-MG and the interval between the laminated gate electrodes of the gate electrodes MG-MG. As a result, the insulating film 9 and the oxide film 8, the laminated structure is left along the side walls on the central region C1, along the sides of the select gate electrodes SGD, SGD, the oxide film 8 remains intact, and, a tapered remnant of the In this case, an exposed corner of the insulating film 9 which is side surface of the laminated gate electrodes of the select gate electrodes SGD opposite to gate electrode MG is slightly etched. Because of the exposed corner is etched toward side surface and an upper surface. As a result, the side surfaces of the insulating film 9 are formed as inclined surfaces inclining from the central region C1 towards the laminated gate electrode sides of the select gate electrodes SGD, SGD on the two sides (or convex curved surfaces curving towards the upper side of the central region C1 side).

Then, high concentration ion implanting is carried out to implant an impurity (e.g., phosphorus when an n-type impurity is adopted) into the exposed substrate 2 at the base of the insulating film 9 located on the sides of the select gate electrodes SGD-SGD. Then, heat treatment needed for activating the impurity is carried out to form the impurity diffusion regions 2b as the high concentration impurity feed-in regions for contacts.

Then, as shown in FIG. 7, with a CVD method, an oxide film 10 is formed as a liner film along the exposed surfaces including the exposed portion of the substrate 2, the insulating film 9, the upper surface of the oxide film 8 (or the upper surface of the nitride film 16 when the upper surface of the nitride film 16 is exposed in the step of operation), and the upper surface of the semiconductor substrate 2.

Then, a CVD method is used to form the nitride film 11 as polish stop on the oxide film 10. Then, on the nitride film 11, the NSG film 12 is formed as an interlayer insulating film. Then, a CMP treatment is carried out to flatten the upper surface of the NSG film 12 in the recesses. In this case, the nitride film 11 works as a polishing stop for the CMP treatment.

Then, an RIE method is adopted to etch back the nitride film 16, and, as the nitride film 16 is removed from above the polysilicon layer 6, the upper surface of the polysilicon layer 6 is exposed. In this case, the upper portions of the nitride film 11 and the oxide film 10 are also removed at the same time.

After removal of the nitride film 16, the photolithographic technology is adopted to form a mask 17. For example, the mask 17 may be formed by the photoresist. The mask 17 is formed so that it at least covers the portion between the select gate electrodes SGD-SGD. In the example shown in FIG. 8, the mask 17 covers near the center on the upper surface of the select gate electrodes SGD.

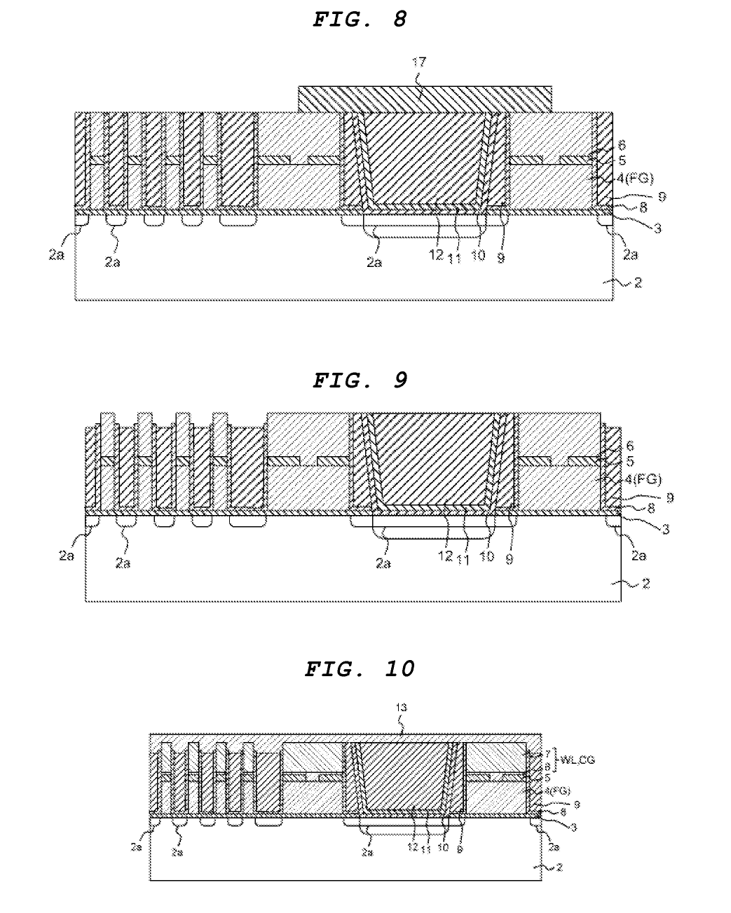

Then, as shown in FIG. 9, the RIE method is adopted to etch back the insulating film 9 in the unmasked portion so that the position of the upper surfaces of the insulating film 9 and the oxide film 8 is recessed from the upper surface of the polysilicon layer 6 downward until the upper portion of the inter-gate insulating film 5. Because the mask 17 covers at least the portion between the select gate electrodes SGD-SGD, the insulating film 9, the oxide film 8, the oxide film 10 and the NSG film 12 in the portion between the select gate electrodes SGD-SGD are not etched back. On the other hand, the oxide film 8 and the insulating film 9 in the portion between the memory cell gate electrodes MG-MG and between the memory cell gate electrode MG and the select gate electrode SGD are etched back.

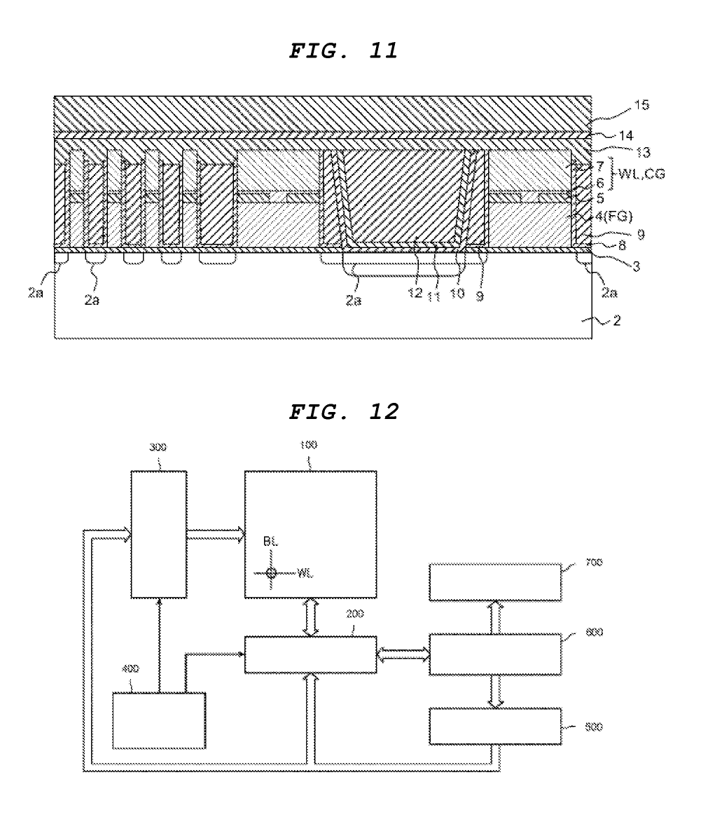

Then, as shown in FIG. 10, a transition metal is formed, on the top surface and the upper side surface of the polysilicon layer 6 by sputtering, and, by RTA (rapid thermal annealing), the upper portion or the entirety of the polysilicon layer 6 is converted to silicide to form the silicide layer 7. Then, the residual metal left unreacted is removed by sulfuric acid/hydrogen peroxide aqueous solution (aqueous solution of sulfuric acid+hydrogen peroxide) treatment. Then, heat treatment is carried out by RTA again to stabilize the silicide layer 7.

Then, the LP-CVD method is to form an oxide film 13. Then, on the oxide film 13, the nitride film 14 is formed using the LP-CVD method and then an oxide film 15 is formed as the upper layer insulating film using the LP-CVD method as shown in FIG. 11.

Then, to achieve the configuration shown in FIG. 3, a photoresist (not shown in the drawing) is coated over the oxide film 15, and conventional photolithographic technology is adopted to form a photoresist pattern for forming the contact holes in the bit line contact region C, and, with the pattern as a mask, anisotropic etching (RIE) is carried out to form the contact holes going through to reach the upper surface of the semiconductor substrate 2. In this case, as shown in FIG. 2, all of the contact holes for the bit line contacts CBa and CBb in the bit line contact region C are formed simultaneously to reach the plural element regions Sa.

Then, as shown in FIG. 3, a barrier metal (not shown in the drawing) is formed in the contact holes, and the CVD method is adopted to have contact material (tungsten) of the bit line contacts CBa and CBb embedded on its inner side. In this case, as shown in FIG. 2, all of the contacts of the bit line contacts CBa and CBb are embedded at the same time.

Then, a multilayer wiring structure is formed on the bit line contacts CBa and CBb. The manufacturing steps of operation after that are irrelevant to the characteristic features of one embodiment, so that they will not be explained in detail. As a result of these steps of operation, the semiconductor memory device 1 can be formed.

According to the present embodiment, the insulating film 9 is etched back so that the position of the upper surfaces of the insulating film 9 and the oxide film 8 is recessed below the upper surface of the polysilicon layer but still above the inter-gate insulating film 5. As the insulating film 9 is etched back, the insulating film 9, the oxide film 8, the oxide film 10 and the NSG film 12 between the select gate electrodes SGD-SGD are not etched back.

The step (height difference) between the upper surface of the broad bit line contact region C and the upper surface of the select gate electrodes SGD is small, so that the oxide film 15 formed later has excellent flatness. More specifically, the step between the upper surfaces of the insulating film 9 and the oxide film 8 and the upper surface of the select gate electrodes SGD in the bit line contact region C is smaller than the step between the upper surfaces of the insulating film 9 and the oxide film 8 and the upper surfaces of the memory cell gate electrodes MG in the portion between the memory cell gate electrodes MG-MG.

On the other hand, because the bit line contact region C is wider than the interval between the memory cell gate electrodes MG-MG, when the mask 17 is not formed for covering, the insulating film 9, the oxide film 8, the oxide film 10 and the NSG film 12 are etched back over a wide area. Due to the etched back bit line contact region C, there is a tendency that when the oxide film 15 is formed thereon, the upper surface thereof mimics the to the etched back shape of the memory cell region, so that the flatness is poor.

Consequently, when the insulating film 9, the oxide film 8, the oxide film 10 and the NSG film 12 are not etched back, there is no need to carry out CMP after the oxide film 15 is deposited, because a sufficiently planar upper surface of the oxide film 15 will result. Even if the CMP is carried out when the oxide film 15 is formed on the non-etched back contact region, the step height is small, and it is possible to increase the manufacturing yield that was previously low due to cracks, crystal defects, and the like generated when the CMP was performed. Here, cracks between the select gate electrodes SGD-SGD often lead to DC defects of the semiconductor memory device, the features described herein have a significant effect in increasing the manufacturing yield of the semiconductor memory devices.

When CMP is not carried out when the oxide film 15 is formed, there is no need to use the nitride film 14 as a polish stop film for CMP. Consequently, it is possible to eliminate the effect of the process temperature required when the nitride film 14 is formed, so that the thermal stress applied on the silicide layer 7 is decreased, and thus it is possible to decrease the defect rate caused by agglomeration, and the like in the silicide layer 7.

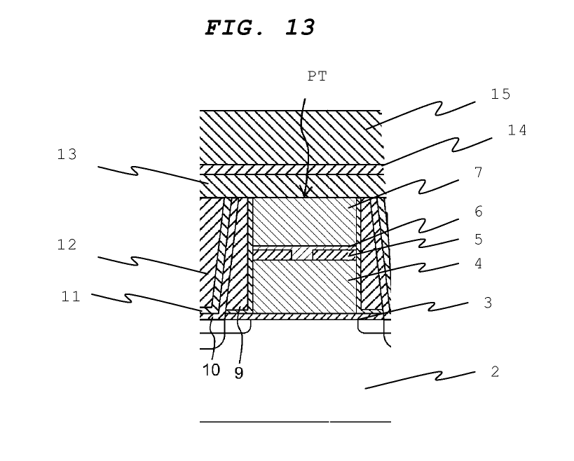

Also, even when CMP is carried out, the quantity of the oxide film 15 to be removed by CMP can be smaller where the film is more uniform. Consequently, it is possible to alleviate the defects caused by the CMP operation, such as scratches of the portions of the word lines WL, scratches of the peripheral circuit regions, and the like (as shown in FIG. 13).

According to the present embodiment, the mask 17 is adopted to cover the portion between the select gate electrodes SGD-SGD. However, one may also adopt a scheme in which the mask 17 is adopted to cover the peripheral circuit regions, such as the regions where the column controller 200, the row controller 300, the high-electric generator 400, the address register 500, the data input/output buffer 600, and the command I/F 700, excluding the memory cell array 100, as shown in FIG. 12. Even when the peripheral circuit regions are covered with the photoresist, there is still no influence on the characteristics of the peripheral circuits, such as characteristics of the resistance in company with variation in the progress of the silicide formation, to a degree that would affect the operation of the semiconductor memory device.

### Other Embodiments

In the above, the configuration has the bit line contacts CBa and CBb arranged near certain select gate electrodes SGD, SGD while they are set in a zigzag pattern in the bit line contact region C. However, one may also adopt a scheme in which they are formed at the center between the select gate electrodes SGD-SGD and at one site for each of the element regions Sa.

The contacts are not limited to the bit line contacts CBa and CBb. The source line contacts may also be used.

There is no specific restriction on the type of the structural materials for the various insulating films (8 to 13) and (14 to 16), as long as they can meet the requirement on the relationship in the etching selectivity (high selection or low selection). In the above explanation, oxide films (8, 9, 10, 12, 13, 15) and nitride films (11, 14, 16) are presented. However, they are merely examples of the silicon oxide-type oxide films and silicon nitride-type nitride films.

In addition, instead of the NSG film 12, one may also use BPSG film, PSG film, and the like, and, instead of the insulating film 9, one may also adopt an air gap structure made of a gap or an insulating film having pores inside it.

As needed, a dummy transistors may be arranged between the select gate transistors Trs1 and the memory cell transistors Trm.

In the example, a NAND-type flash memory device is presented. However, the present disclosure also can be adopted on the NOR-type flash memory device, the EEPROM-type and other semiconductor memory devices.

While certain embodiments have been described, these embodiments have been presented by way of example only, and are not intended to limit the scope of the embodiments. Indeed, the novel embodiments described herein may be embodied in a variety of other forms; furthermore, various omissions, substitutions and changes in the form of the embodiments described herein may be made without departing from the spirit of the embodiments. The accompanying claims and their equivalents are intended to cover such forms or modifications as would fall within the scope and spirit of the embodiments.

What is claimed is:

1. A semiconductor memory device comprising:
a substrate
a memory cell array having a plurality of memory cell transistors disposed on the substrate, a first select gate transistor disposed adjacent to one of the memory cell transistor, and a second select gate transistor disposed adjacent to the first select gate transistor opposite side said one of the memory cell transistor; and
an insulating film formed between the memory cell transistors and formed between the first select gate transistor and the second select gate transistor, and the insulating film having a first surface which is between the first select transistor and the second select transistors and a second surface which is between the memory cell transistors
wherein a first distance between an upper surface of the first select transistor and the first surface is smaller than a second distance between the first surface and the second surface.

2. The device of claim 1 further comprising, a bit line, and
a contact electrically connected to the first select gate transistor and the bit line,
wherein the memory cell transistors are electrically connected in series to a first direction, the bit line extents to the first direction, and the contact disposed in the insulating film between the first select transistor and the second select transistor.

3. The device of claim 1, wherein the insulating film has a first insulating film and a second insulating film between the first insulating film and the first select gate transistor, and a third distance from the surface of the substrate and the first insulating film is equal to a fourth distance from the surface of the substrate and the second insulating film.

4. The device of claim 1 further comprising, a peripheral transistor disposed in a peripheral region, and
a third insulating film disposed on the peripheral transistor, wherein
a fourth distance between an upper surface of the peripheral transistor and an upper surface of the third insulating film is smaller than the second distance.

5. The device of claim 1 wherein a fifth distance between the memory cell transistors is smaller than a sixth distance between the first select gate transistor and the second select gate transistor.

6. A semiconductor memory device comprising:
plural memory cells arranged on a semiconductor substrate;
plural select transistors for selecting the memory cell;
an insulating material interposed between plural memory cells and between the plural select transistors; and
an insulating layer located on the adjacent memory cells and the adjacent select transistors and having an outer surface spaced from the insulating material interposed between plural memory cells and between the plural select transistors and an inner surface contacting the insulating material interposed between plural memory cells and between the plural select transistors;
wherein, the distance between the outer and inner surface of the insulating layer, is smaller where the insulating layer contacts insulating material interposed between gate electrodes than where the lower surface of the insulating layer contacts insulating material interposed between plural memory cells.

7. The semiconductor memory device of claim 6, further including:
a substrate
a dielectric layer overlying the substrate and within which the memory cells and gate electrodes are located.

8. The semiconductor memory device of claims 7, further including an insulating film layer interposed between the memory cells and gate electrodes and the dielectric layer.

9. The semiconductor device of claim 8, wherein the memory cells include memory cell gates contacting the insulating layer, and;
the memory cell gates extend inwardly of the insulating layer a further distance that the portion of the insulating film layer contacting the memory cell gates.

10. The semiconductor memory device of claim 8, wherein the gate electrodes include an outer surface opposed to the substrate and in contact with the insulating layer,
at least two opposed side walls extending from the outer surface in the direction of the substrate,
and the insulating film contacting the sidewalls, wherein a portion of at least one of the side walls is not contacting the insulating film.

11. The semiconductor memory device of claim 10, wherein the outer surfaces of the gate electrodes and the memory cell gates extend outwardly from the substrate the same distance.

12. The semiconductor memory device of claim 11, wherein a contact extends through the insulating layer, the insulating material and the insulating film and contacts the substrate.

13. The semiconductor memory device of claim 12, wherein the insulating film includes a first sub-film and a second sub-film.

14. The semiconductor memory device of claim 12, wherein the distance of the outer surface of the insulating layer from the substrate is uniform over the span of the contact location and an adjacent memory cell gate.

15. A manufacturing method of semiconductor memory device, comprising:
forming plural memory cells and plural select transistors for selecting the memory cell to carry out record or read on a semiconductor substrate;
forming an insulating film between the adjacent memory cells and between the adjacent select transistors;
forming a mask on the upper surface of the insulating film between at least a portion of the upper surface of the select transistors and the select transistors;
etching the insulating film on the memory cells to a position spaced from the upper surface of the gate electrodes of the memory cells;
removing the mask;
forming a contact via through the insulating film between the select transistors; and
forming wiring that is electrically connected to the select transistors via the contacts.

16. The method of claim 15, further including the step of forming an insulating layer over the gate electrodes, memory cells and insulating film prior to forming the contact via.

17. The method of claim 16, further including the step of forming the contact via without previously polishing the insulating layer.

18. The method of claim 15, further including recesses between the location of adjacent select gate transistors and between the select gate transistors and the memory cell transistors.
